(19) United States
(12) Patent Application Publication
(10) Pub. No.: US 2011/0186905 A1
(43) Pub. Date: Aug. 4, 2011

(54) OLED DEVICE WITH COVERED SHUNT LINE

(75) Inventors: Holger Schwab, Aachen (DE); Edward W. A. Young, Maastricht (NL); Jeroen Buul, Budel (NL)

(73) Assignee: KONINKLIJKE PHILIPS ELECTRONICS N.V., EINDHOVEN (NL)

(21) Appl. No.: 13/121,422

(22) PCT Filed: Sep. 25, 2009
(86) PCT No.: PCT/IB2009/054209

§ 371 Date: Mar. 29, 2011

(30) Foreign Application Priority Data
Oct. 2, 2008 (EP) 08105477.7

(51) Int. Cl. H01L 51/52; H01L 51/56

(52) U.S. Cl. 257/99; 438/22; 257/E51.019; 257/E51.001

(57) ABSTRACT

The invention relates to an OLED device with a substrate (1), a conductor layer (3), an organic layer (2) as an active layer, and a shunt line (4) as an additional current distribution channel, wherein the conductor layer (3) is provided on the substrate (1), wherein the shunt line (4) is provided on the conductor layer (3), wherein the shunt line (4) is at least partially covered by an electrically insulating layer (5), and wherein the organic layer (2) is provided on top of the conductor layer (3) and the covered shunt line (4). In this way, such an OLED device is provided which prevents short circuit formation and, thus, device failure.

### FIELD OF THE INVENTION

The invention relates to the field of OLED devices and methods of manufacturing OLED devices.

### BACKGROUND OF THE INVENTION

Organic light-emitting diodes (OLEDs) follow the same working principle as inorganic LEDs but use organic materials as an active light emitting material. On a non-conducting carrier a transparent electrode is applied which serves as the carrier for the organic material. OLEDs provide for several advantages over LEDs and other display and lighting types. As OLEDs are light-emitting over the whole area of the substrate they can act as large area light sources, in contrast to inorganic LEDs where the light emission is limited to a small surface area. When using flexible substrates such as plastic foils they can even be made flexible. Thus, OLED devices offer the opportunity to manufacture flexible, large area light sources.

In OLED devices as well as in solar cells a similar device set-up is used. On a transparent substrate, like glass or PET, a transparent conductor is applied. These conductors allow visible light to enter and leave the device while being able to carry the current required to operate such a device. The conductivity of these transparent electrodes is limited which limits the size of the devices and gives rise to a inhomogeneous light emission due to a voltage drop across this conductor. In order to overcome this limitation additional current distribution channels made of metals can be used.

These lines can be made in various ways. Techniques like printing of metal pastes, laser transfer of metals or laser lithography of metals are used. In all cases these shunt lines require an additional passivation process due to high electrical field strength in the vicinity of these metal lines.

During manufacturing an OLED, the organic material is deposited with a constant rate per surface area. Typically, the organic material is deposited onto a transparent conductor layer which is provided on the substrate. On this conductor layer, shunt lines as described above are provided. As a shunt line represents a disturbance in the planarity of the surface, the layer growing on the side surfaces of a respective shunt line is thinner compared to the remainder of the substrate. If a voltage is applied to the transparent conductor and therefore to the shunt lines, the field strength in the area of the shunt lines is higher compared to the remainder of the substrate. This gives rise to enhanced device degradation in this area and the risk for short circuit formation and therefore to fatal device failure.

### SUMMARY OF THE INVENTION

It is the object of the invention to provide such an OLED device and such a method for manufacturing an OLED device which prevent short circuit formation and, thus, device failure.

This object is achieved by an OLED device with a substrate, a conductor layer, an organic layer as an active layer, and a shunt line as an additional current distribution channel, wherein the conductor layer is provided on the substrate, wherein the shunt line is provided on the conductor layer, wherein the shunt line is at least partially covered by an electrically insulating layer, and wherein the organic layer is provided on top of the conductor layer and the covered shunt line.

In general, the OLED comprises an opposite electrode. According to a preferred embodiment of the invention, the electrically insulating layer is adapted for avoiding that a current can be drawn from the shunt line to the opposite electrode. In this way, short circuit formation and, thus, device failure can be efficiently avoided.

Generally, the electrically insulating layer may cover the shunt line only partly, i.e. in some areas. However, according to a preferred embodiment of the invention, the electrically insulating layer completely covers the shunt line. Further, according to a preferred embodiment of the invention, multiple shunt lines, preferably a grid of shunt lines, is provided which are covered by the electrically insulating layer. Furthermore, the conductor layer is at least partially, preferably completely, i.e. in all areas, transparent.

According to a preferred embodiment of the invention, the electrically insulating layer partly also covers the conductor layer. With respect to this, it is especially preferred that the electrically insulating layer covers a region of the conductor layer which is in the direct vicinity of the shunt line, the width of this region corresponding to the thickness of the insulating layer. This serves for further enhancing short circuit prevention.

In general, the electrically insulating layer may be comprised of different materials. According to a preferred embodiment of the invention, the electrically insulating layer comprises a photo resist. Further, the electrically insulating layer can be deposited onto the shunt line in different ways. However, according to a preferred embodiment of the invention, the electrically insulating layer was deposited by ink jet printing, gravure printing, or/and screen printing.

Moreover, according to a preferred embodiment of the invention, the thickness of the electrically insulating layer is ≧80 nm, more preferably ≧200 nm, most preferably ≧1 μm, and/or ≦5 μm, more preferably ≦3 μm, and most preferably 2 μm. In this way efficient short circuit prevention is provided while still keeping the non-transparent regions at an acceptable degree.

Above mentioned object is further addressed by a method of manufacturing an OLED device, the OLED device comprising a substrate, a conductor layer, an organic layer as an active layer, and a shunt line as an additional current distribution channel, wherein the conductor layer is provided on the substrate, wherein the shunt line is deposited on the conductor layer, wherein an insulating layer is deposited on the shunt line, the electrically insulating layer at least partially covering the shunt line, and wherein the organic layer is deposited on top of the conductor layer and the covered shunt line.

Preferred embodiments of this method according to the invention relate to the preferred embodiments of the device according to the invention described above.

Especially, according to a preferred embodiment of the invention, the electrically insulating layer is deposited by ink jet printing, gravure printing, or/and screen printing. With respect to this, according to a preferred embodiment of the invention, after the deposition of the organic material a baking step is applied. Preferably this baking step is done at temperatures of ≧150° C. and ≦180° C. Further, the baking step is preferably done for a period of ≧20 min and ≦40 min.

### BRIEF DESCRIPTION OF THE DRAWINGS

These and other aspects of the invention will be apparent from and elucidated with reference to the embodiments described hereinafter.

In the drawings:

FIG. 1a depicts a substrate of an OLED device during deposition of organic material;

FIG. 1b depicts the substrate after deposition of the organic material;

FIG. 2a depicts a substrate of an OLED device according to an embodiment of the invention with a shunt line; and

FIG. 2b depicts the substrate of the OLED device according to the embodiment of the invention after covering the shunt line with an electrically insulating layer and after deposition of an organic layer.

### DETAILED DESCRIPTION OF EMBODIMENTS

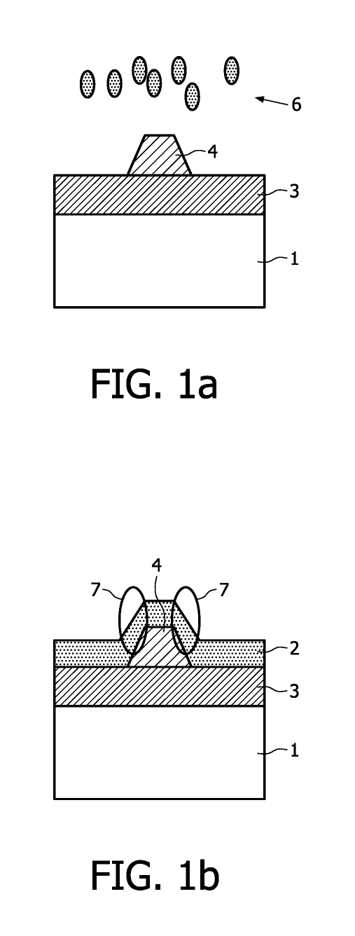

In FIG. 1a, a substrate 1 during deposition of organic material 6 is shown. The substrate 1 is covered with a transparent conductor layer 3 which is provided with a shunt line 4. This shunt line 4 is part of a grid of shunt lines covering the conductor layer 3 and, thus, serving as an additional current distribution channel.

The organic material 6 is deposited onto the transparent conductor layer 3 and the shunt line 4 with a constant rate per surface area. Since the shunt line represents a disturbance in the planarity of the surface of this structure, growing of organic material 6 on the shunt line 4 is thinner compared to the remainder of the structure. As already mentioned above, if a voltage is applied to the transparent conductor layer 3 and, thus, to the shunt line 4, the field strength in the side areas 7 of the shunt line 4 is higher than in the remainder, giving rise to short circuit formation and device failure.

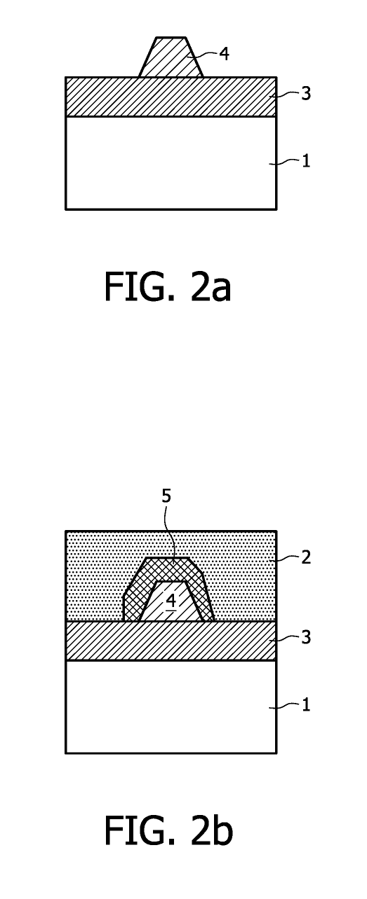

According to the embodiment of the invention shown in FIGS. 2a and 2b, the high field strength in the side areas 7 of the shunt line 4 is overcome since the shunt line 4 is coated by an electrically insulating material 5, such as photo resist. This resist avoids that a current can be drawn from the bus bars towards an opposite electrode of the OLED (not shown). Several deposition methods are possible for this process, such as ink jet printing, gravure printing, screen printing, etc.

Typical photo resists layers can be made as thin as 80 nm in order to provide sufficient electrical insulation. For laser deposited shunt lines the layer thickness of the organic layer is preferably similar or larger than the typical roughness of the layer. In AFM (atomic force microscope) measurements the roughness was measured to be in the order of 100-500 nm. A layer thickness of 1-2 μm is therefore preferably selected for the photo resist layer.

According to the embodiment of the invention described here, as deposition method screen printing was selected. In this case, the minimum line width of the insulating layer 5 is given by the maximum width of the metal shunt line 4 plus the alignment accuracy of the screen printed pattern with respect to the metal pattern. Typical experimental values for the metal lines are 80-150 μm and the alignment accuracy is in the order of 200 μm to 300 μm.

After the deposition of the organic material 6, according to the present embodiment of the invention, a baking step is applied. This step serves two purposes: At first, the layer adhesion between organics and the metal layer is enhanced. In addition, the organic layer softens and slightly flows thereby filling small gaps in the insulation layer 5. The baking step is done at temperatures between 150° C. and 180° C. for a period of 20 min to 40 min.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. An OLED device with a substrate, a conductor layer, an organic layer as an active layer, and a shunt line as an additional current distribution channel, wherein the conductor layer is provided on the substrate, wherein the shunt line is provided on the conductor layer, wherein the shunt line is at least partially covered by an electrically insulating layer, and wherein the organic layer is provided on top of the conductor layer and the covered shunt line.

2. The OLED device according to claim 1, wherein an opposite electrode is provided and the electrically insulating layer is adapted for avoiding that a current can be drawn from the shunt line to the opposite electrode.

3. The OLED device according to claim 1, wherein the electrically insulating layer completely covers the shunt line.

4. The OLED device according to claim 1, wherein multiple shunt lines, preferably a grid of shunt lines (4), is provided which are covered by the electrically insulating layer.

5. The OLED device according to claim 1, wherein the conductor layer is at least partially transparent.

6. The OLED device according to claim 1, wherein the electrically insulating layer covers a region of the conductor layer which is in direct vicinity of the shunt line, the width of this region corresponding to the thickness of the insulating layer.

7. The OLED device according to claim 1, wherein the electrically insulating layer comprises a photo resist.

8. The OLED device according to claim 1, wherein the electrically insulating layer was deposited by ink jet printing, gravure printing, or/and screen printing.

9. The OLED device according to claim 1, wherein the thickness of the electrically insulating layer ranges from 80 nm to 5 μm.

10. A method of manufacturing an OLED device, the OLED device comprising a substrate, a conductor layer, an organic layer as an active layer, and a shunt line as an additional current distribution channel, wherein the conductor layer is provided on the substrate, wherein the shunt line is deposited on the conductor layer, wherein an electrically insulating layer is deposited on the shunt line, the electrically insulating layer at least partially covering the shunt line, and wherein the organic layer is deposited on top of the conductor layer and the covered shunt line.

11. The method according to claim 10, wherein the electrically insulating layer is deposited by ink jet printing, gravure printing, or/and screen printing.

12. The method according to claim 10, wherein after deposition of the organic material for the organic layer a baking step is applied.

13. The method according to claim 12, wherein the baking step is done at a temperature of ≧150° C. and ≦180° C.

14. The method according to claim 13, wherein the baking step is done for a period of ≧20 min and ≦40 min.

15. The OLED device according to claim 9, wherein the thickness of the electrically insulating layer ranges from 200 nm to 3 μm.

16. The OLED device according to claim 9, wherein the thickness of the electrically insulating layer ranges from 1 μm to 2 μm.
